(19) United States
(12) Patent Application Publication
(10) Pub. No.: US 2011/0045207 A1
(43) Pub. Date: Feb. 24, 2011

(54) METHOD FOR PRODUCING CARBON NANOWALLS

(76) Inventors: Masaru Hori, Aichi (JP); Mineo Hiramatsu, Aichi (JP); Hioryuki Kano, Aichi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/450,399

(22) PCT Filed: Mar. 24, 2008
(86) PCT No.: PCT/JP2008/055441

§ 371 Date: Dec. 30, 2009

(30) Foreign Application Priority Data
Mar. 25, 2007 (JP) 2007-078038

(51) Int. Cl. C23C 16/32; C23C 16/50; B82Y 30/00; B82Y 40/00

(52) U.S. Cl. 427/577; 977/700; 977/891

(57) ABSTRACT

To improve the crystallinity of carbon nanowalls.

The method of the invention for producing carbon nanowalls, includes forming carbon nanowalls on a surface of a base in a plasma atmosphere containing hydrogen and a raw material containing at least carbon and fluorine as its constituent elements, oxygen plasma is added to the plasma atmosphere. The hydrogen plasma was generated through injecting, to the plasma generation site, hydrogen radicals generated at a site different from the plasma atmosphere. The raw material is at least one member selected from among C₂F₆, CF₄, and CHF₃.

### TECHNICAL FIELD

The present invention relates to a method for producing carbon nanowalls having good crystallinity.

### BACKGROUND ART

By virtue of their microstructures, carbon nanowalls have been envisaged for application to fuel cells and electronic devices such as field emitters. In Patent Document 1, the present inventors previously disclosed a method for producing carbon nanowalls.

### Patent Document 1: WO2005/021430

### DISCLOSURE OF THE INVENTION

### Problems to be Solved by the Invention

According to the method disclosed in Patent Document 1, a gas containing carbon and fluorine (e.g., C₂F₆, CF₄, or CHF₃) is introduced to a space between a positive electrode and a negative electrode in a reaction chamber, and RF power is applied to these electrodes, whereby a plasma containing carbon and fluorine is provided. Hydrogen plasma is formed in a chamber different from the reaction chamber, and hydrogen radicals are injected into the plasma atmosphere provided in the reaction chamber. Carbon nanowalls are grown on a glass or silicon substrate placed on the negative electrode.

This method can grow carbon nanowalls of high quality without use of a catalyst. However, demand has arisen for development of a method for growing carbon nanowalls of higher quality.

In view of the foregoing, an object of the present invention is to improve the crystallinity of carbon nanowalls.

### Means for Solving the Problems

In a first aspect of the present invention, there is provided a method for producing carbon nanowalls, comprising forming carbon nanowalls on a surface of a base in a plasma atmosphere containing hydrogen and a raw material containing at least carbon and fluorine as its constituent elements, characterized in that oxygen atom radicals or radicals of an oxygen-atom-containing molecule are added to the plasma atmosphere.

The present inventors have found that carbon nanowalls of high quality are grown on a substrate by adding oxygen atom radicals or radicals of an oxygen-atom-containing molecule to a plasma atmosphere containing carbon and fluorine. The raw material employed is preferably at least one of C₂F₆, CF₄, and CHF₃. Examples of the oxygen atom radicals and the radicals of an oxygen-atom-containing molecule include O radicals, OH radicals, and ON radicals. When such an oxygen-atom-containing molecule is supplied in the form of gas into a reaction chamber, and radicals of the molecule are generated in the reaction chamber, an oxygen-atom-containing gas is supplied to a substrate. The oxygen-atom-containing gas may be, for example, oxygen gas, CO₂, or H₂O. The O radical concentration of the plasma atmosphere may be determined through observation of light emitted from oxygen atoms in the plasma atmosphere, and the O radical or OH radical concentration of the plasma atmosphere may be appropriately controlled by regulating the feed rate of an oxygen-atom-containing gas, to thereby control growth of carbon nanowalls. When an oxygen-atom-containing gas (e.g., oxygen gas, carbon dioxide gas, water vapor, or nitrogen dioxide gas) is supplied to the reaction chamber, preferably, oxygen atom radicals or radicals of an oxygen-containing molecule are supplied in the vicinity of a base on which carbon nanowalls are formed, or supplied in parallel to the growth surface of the base. As has been shown, in such a case, even when the flow rate of the oxygen-atom-containing gas is high (e.g., about 10 sccm), a plasma thereof is stably formed, and the base is not etched. As has also been shown, when such an oxygen-atom-containing gas is supplied at a location away from the base, the resultant plasma is unstable, and the base is etched. Alternatively, oxygen atom radicals or radicals of an oxygen-atom-containing molecule may be generated in a chamber different from the reaction chamber, and the radicals may be supplied in the vicinity of the base or in parallel to the growth surface of the base.

Preferably, hydrogen radicals are generated at a site different from the plasma atmosphere for growing carbon nanowalls on a substrate, and the hydrogen radicals are injected into the plasma atmosphere. According to the aforementioned production method, one or more of conditions (e.g., the composition and feed rate of the radicals injected into the plasma atmosphere) may be controlled independently of or in conjunction with one or more of other production conditions. That is, the production method provides higher flexibility in controlling production conditions, as compared with the case where no radicals are injected from outside the plasma atmosphere. This is advantageous from the viewpoint of production of carbon nanowalls exhibiting properties of interest (e.g., the thickness, height, density on the substrate, smoothness, and surface area of formed nanowalls) and/or characteristics of interest (e.g., electrical characteristics such as field emission characteristics).

As used herein, the term “carbon nanowall(s)” is used to refer to a carbon nano-scale structure (hereinafter may be referred to as a “carbon nanostructure”) which extends two-dimensionally. Carbon nanowalls are formed of graphene sheets which extend two-dimensionally and which are provided upright on a surface of a base, and each nanowall is formed of a single layer or multiple layers. As used herein, the expression “extend two-dimensionally” refers to the case where the lengths of a carbon nanowall in longitudinal and lateral directions are sufficiently greater than the thickness (width) thereof. Such a carbon nanowall may be formed of multiple layers, a single layer, or a pair of layers (with a space provided therebetween). The upper surfaces of carbon nanowalls may be covered so that cavities are provided therebetween. For example, carbon nanowalls have a thickness of about 0.05 to about 30 nm, and a longitudinal or lateral length of about 100 nm to about 10 μm. In general, a carbon nanowall is expressed as “extending two-dimensionally,” since the lengths of the carbon nanowall in longitudinal and lateral directions are much greater than the width thereof, and thus can be controlled.

Typically, carbon nanowalls produced through the aforementioned production method are of a carbon nanostructure formed of upright walls extending from the surface of a base in generally the same direction. As used herein, the term “plasma atmosphere” refers to an atmosphere in which at least a portion of a substance forming the atmosphere is in an ionized state (in a state of plasma; i.e., in a state of a mixture containing, for example, charged particles such as atomic ions, molecular ions, or electrons, and neutral particles such as atomic radicals or molecular radicals).

In a preferred mode of the production method disclosed herein, the plasma atmosphere is provided by forming a plasma of a raw material(s), hydrogen plasma, and oxygen plasma in the reaction chamber. Alternatively, a plasma of a raw material(s), hydrogen plasma, and oxygen plasma may be formed outside of the reaction chamber, and the thus-formed plasmas may be introduced into the reaction chamber, to thereby form the plasma atmosphere therein. Alternatively, only a plasma of a raw material(s) may be formed in the reaction chamber; oxygen radicals or OH radicals, and hydrogen radicals may be generated in a chamber different from the reaction chamber; and these radicals may be injected into the plasma atmosphere in the reaction chamber. Alternatively, a plasma of a raw material(s) and oxygen plasma may be formed in the reaction chamber; only hydrogen radicals may be generated in a chamber different from the reaction chamber; and the hydrogen radicals may be injected into the plasma atmosphere in the reaction chamber. Alternatively, a plasma of a raw material(s) and hydrogen plasma may be formed in the reaction chamber; only oxygen radicals or OH radicals may be generated in a chamber different from the reaction chamber; and the oxygen radicals or the OH radicals may be injected into the plasma atmosphere in the reaction chamber.

In a preferred method for generating radicals from a radical source material, the radical source material is irradiated with an electromagnetic wave. Examples of the electromagnetic wave which may be employed in such a method include microwaves and high-frequency waves (UHF waves, VHF waves, and RF waves). Irradiation of a VHF wave or an RF wave is particularly preferred. According to such a method, the degree of decomposition of a radical source material (i.e., the amount of radicals generated) can be readily controlled by varying, for example, frequency and/or input electric power. Therefore, such a method is advantageous in that conditions for production of carbon nanowalls (e.g., the amount of radicals supplied into the plasma atmosphere) are readily controlled.

As has been well known, the term “microwave” refers to an electromagnetic wave having a frequency of about 1 GHz or more; “UHF wave” refers to an electromagnetic wave having a frequency of about 300 to about 3,000 MHz; “VHF wave” refers to an electromagnetic wave having a frequency of about 30 to about 300 MHz; and “RF wave” refers to an electromagnetic wave having a frequency of about 3 to about 30 MHz. In another preferred method for generating radicals from a radical source material, DC voltage is applied to the radical source material. Generation of radicals from a radical source material may also be carried out through, for example, a method in which the radical source material is irradiated with light (e.g., visible light or UV rays), a method in which the radical source material is irradiated with an electron beam, or a method in which the radical source material is heated. Alternatively, generation of radicals from a radical source material may be carried out by bringing the radical source material into contact with a heated catalytic-metal-containing member (i.e., through heat and catalytic action). The aforementioned catalytic metal may be one or more species selected from among, for example, Pt, Pd, W, Mo, and Ni.

Radicals injected into the plasma atmosphere preferably contain at least hydrogen radicals (i.e., atomic hydrogen, hereinafter may be referred to as “H radicals”), and oxygen radicals (i.e., atomic oxygen, hereinafter may be referred to as “O radicals”) or OH radicals. Preferably, H radicals are generated through decomposition of a radical source material containing at least hydrogen as its constituent element, and the thus-generated H radicals are injected into the plasma atmosphere. Such a radical source material is particularly preferably hydrogen gas (H₂).

Various raw materials containing at least carbon as a constituent element may be employed. Only a single raw material may be employed, or two or more raw materials may be employed in any proportions. Examples of preferred raw materials include materials containing at least carbon and hydrogen as constituent elements (e.g., hydrocarbon). Other examples of preferred raw materials include materials containing at least carbon and fluorine as constituent elements (e.g., fluorocarbon).

The raw material employed may be a material containing carbon, hydrogen, and fluorine as essential constituent elements (e.g., fluorohydrocarbon). As described hereinbelow, particularly when a material containing carbon and fluorine as constituent elements (e.g., C₂F₆ or CF₄) is employed, carbon nanowalls having good shape are formed. Also, when a material containing carbon, hydrogen, and fluorine as constituent elements (e.g., CHF₃) is employed, carbon nanowalls having good shape are formed.

The present inventors have found that the amount of H radicals injected into a reaction zone can be controlled by varying the ratio of the flow rate of H₂ gas (i.e., radical source material) to that of a raw material gas, whereby the shape, interwall spacing, thickness, or size of carbon nanowalls formed can be controlled. Therefore, properties of carbon nanowalls formed can be controlled by regulating the feed rate of the radicals into the reaction zone.

In a preferred mode of the production method disclosed herein, at least one of the conditions for producing carbon nanowalls is controlled on the basis of the concentration of at least one type of radicals in the reaction chamber (e.g., the concentration of at least one type of radicals selected from among carbon radicals, hydrogen radicals, fluorine radicals, and oxygen radicals). Examples of the production condition which may be controlled on the basis of such a radical concentration include the feed rate of a raw material(s), conditions required for forming a plasma of a raw material(s) (severity of plasma formation conditions), and the amount of radicals (typically, H radicals) injected. Preferably, such production conditions are controlled on the basis of the feedback results of the aforementioned radical concentration. According to the production method, carbon nanowalls exhibiting properties and/or characteristics of interest can be more effectively produced.

In a preferred embodiment of the production method of the present invention, no metal catalyst is present on a base. According to the production method of the present invention, carbon nanowalls are effectively formed in the absence of a metal catalyst on the surface of the base.

### Effects of the Invention

According the present invention, since oxygen-atom-containing radicals (e.g., O radicals or OH radicals) are added to a plasma atmosphere containing carbon, fluorine, and hydrogen, carbon nanowalls having good crystallinity can be grown on a substrate. Particularly, the method of the present invention can produce carbon nanowalls which have no branching in a height direction and extend smoothly.

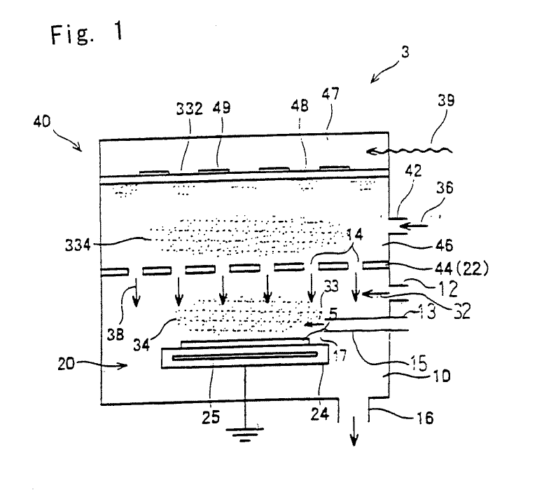

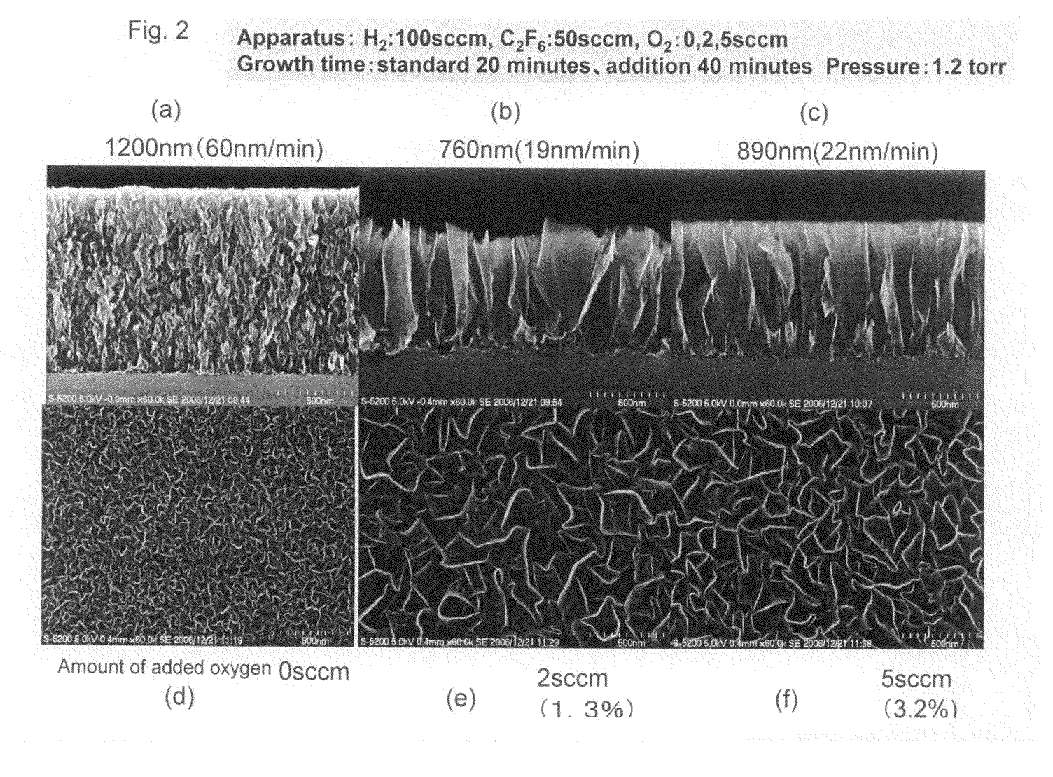

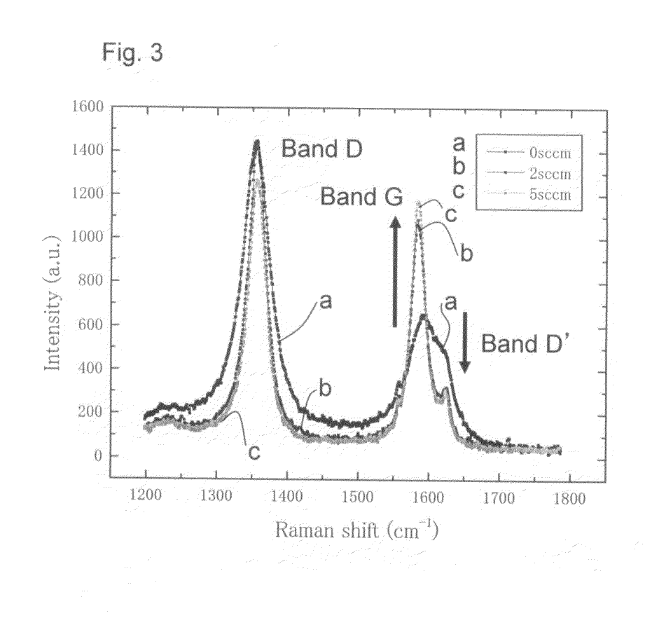

### BRIEF DESCRIPTION OF THE DRAWINGS

[FIG. 1] FIG. 1 is a schematic representation of a production apparatus for carrying out a production method according to a specific embodiment of the present invention.

[FIG. 2] FIG. 2(a) is an SEM image of cross sections of carbon nanowalls produced through a conventional production method; FIG. 2(b) or 2(c) is an SEM image of cross sections of carbon nanowalls produced through a production method according to a specific embodiment of the present invention; FIG. 2(d) is an SEM image of top surfaces of carbon nanowalls produced through the conventional production method; and FIG. 2(e) or 2(f) is an SEM image of top surfaces of carbon nanowalls produced through the production method according to a specific embodiment of the present invention.

[FIG. 3] FIG. 3 shows Raman spectra of carbon nanowalls produced through a conventional production method and production methods according to specific embodiments of the present invention.

### BEST MODES FOR CARRYING OUT THE INVENTION

Preferred embodiments of the present invention will next be described in detail. Technical matters that are necessary for carrying out the present invention but are not specifically referred to herein should be understood to be of design choice that those skilled in the art are recognized on the basis of conventional techniques. The present invention can be carried out on the basis of technical matters disclosed herein and techniques generally known to those skilled in the art.

Various raw materials containing at least carbon as a constituent element may be employed for producing carbon nanowalls. The element which can constitute such a raw material together with carbon is one or more elements selected from among, for example, hydrogen, fluorine, chlorine, bromine, nitrogen, and oxygen. Examples of preferred raw materials include a raw material virtually consisting of carbon and hydrogen, a raw material virtually consisting of carbon and fluorine, and a raw material virtually consisting of carbon, hydrogen, and fluorine. For example, a fluorocarbon (e.g., C₂F₆) or a fluorohydrocarbon (e.g., CHF₃) is preferably employed. Such a raw material having a linear, branched, or cyclic molecular structure may be employed. Generally, a raw material which is in a gaseous state at ambient temperature and ambient pressure (i.e., a raw material gas) is preferably employed. Only a single raw material may be employed, or two or more raw materials may be employed in any proportions. The type (composition) of a raw material(s) employed may be unchanged throughout production stages (e.g., a growth process) of carbon nanowalls, or may be varied depending on the production stages. The type (composition) of a raw material(s) employed, the method for supplying the raw material(s), or other conditions may be appropriately determined in consideration of properties (e.g., wall thickness) and/or characteristics (e.g., electrical characteristics) of a carbon nanostructure of interest.

The radical source material employed is preferably a material containing at least hydrogen as its constituent element. Preferably, a radical source material which is in a gaseous state at ambient temperature and ambient pressure (i.e., a radical source gas) is employed. Hydrogen gas (H₂) is a particularly preferred radical source material. The radical source material employed may be a material which can generate H radicals through decomposition (e.g., a hydrocarbon such as CH₄). Only a single radical source material may be employed, or two or more radical source materials may be employed in any proportions.

In the production method disclosed herein, radicals are injected into an atmosphere containing a plasma of a raw material(s) and oxygen plasma. Thus, the raw material plasma, oxygen plasma, and radicals (typically, H radicals) are mixed together. Specifically, radicals (H radicals) are present at high concentration in the raw material plasma atmosphere. Oxygen radicals and hydrogen radicals may be injected into the raw material plasma atmosphere. Carbon nanowalls are formed (grown) on a base through deposition of carbon thereon from the atmosphere containing the raw material plasma, oxygen plasma, and radicals. Examples of the base which may be employed include a base in which at least a region on which carbon nanowalls are formed is made of Si, SiO₂, Si₃N₄, GaAs, Al₂O₃, or a similar material. The entirety of the base employed may be made of any of the aforementioned materials. According to the aforementioned production method, carbon nanowalls can be formed directly on a surface of the aforementioned base without using a catalyst such as nickel-iron. However, a catalyst such as Ni, Fe, Co, Pd, or Pt (typically, a transition metal catalyst) may be employed. For example, a thin film (e.g., a film having a thickness of about 1 to about 10 nm) of any of the aforementioned catalysts may be formed on a surface of the aforementioned base, and carbon nanowalls may be formed on the catalyst thin film. No particular limitation is imposed on the outer shape of the base employed. Typically, a plate-like base (substrate) is employed.

### EMBODIMENT 1

FIG. 1 shows a configuration of an apparatus for producing carbon nanowalls. As shown in FIG. 1, the apparatus 3 according to Embodiment 1 includes radical generation device 40, and the radical generation device 40 includes a plasma formation chamber 46 provided above a reaction chamber 10. The plasma formation chamber 46 is separated from the reaction chamber 10 by a partition 44 which is provided so as to face the surface of the substrate 5 on which carbon nanowalls are formed. A waveguide 47 for guiding microwaves 39 is provided above the plasma formation chamber 46. The microwaves are introduced into the plasma formation chamber 46 through quartz windows 48 by means of slot antennas 49, to thereby form a high-density plasma 332. The plasma 332 is caused to diffuse in the plasma formation chamber 46 (plasma 334), whereby radicals 38 are generated. Bias voltage may be appropriately applied to the partition 44. For example, bias voltage may be applied between the partition 44 and the plasma 334 in the plasma formation chamber 46, or between the partition 44 and a plasma atmosphere 34 in the reaction chamber 10. The direction of bias voltage may be appropriately varied. Preferably, the apparatus is configured so that negative bias voltage can be applied to the partition 44.

Ions generated from the plasma 334 are electrically neutralized at the partition 44, to thereby generate the radicals 38. In this case, percent neutralization may be appropriately increased through application of an electric field to the partition 44. Energy may be applied to the neutral radicals. Numerous through-holes are distributed in the partition 44. The radicals 38 are introduced through these through-holes (serving as numerous radical inlets 14) into the reaction chamber 10 and diffused as is therein, and then the radicals 38 are injected into the plasma atmosphere 34. As shown in FIG. 1, the inlets 14 are provided in a direction parallel to the top surface of the substrate 5 (i.e., the surface on which carbon nanowalls are formed).

With this configuration of the apparatus 3, the radicals 38 can be more uniformly introduced to a wider region in the reaction chamber 10. Therefore, carbon nanowalls can be effectively formed on a wider region (area) of the substrate 5. In addition, carbon nanowalls having more uniform structural features (properties, characteristics, etc.) can be formed at any portions of the substrate surface. According to Embodiment 1, one or more of these effects can be achieved.

The partition 44 may be coated with a material exhibiting high catalytic performance (e.g., Pt), or may be made of such a material itself. When an electric field is applied between the partition 44 having such a structure and the plasma atmosphere 34 (typically, negative bias voltage is applied to the partition 44), ions contained in the plasma atmosphere 34 are accelerated, and the partition 44 is sputtered by the ions, whereby atoms (e.g., Pt) or clusters exhibiting catalytic performance can be injected into the plasma atmosphere 34.

In a carbon nanowall formation process, employed are the radicals 38 (typically, H radicals) injected from the plasma formation chamber 46, radicals and/or ions containing at least carbon, the radicals and/or ions being generated in the plasma atmosphere 34, and atoms or clusters exhibiting catalytic performance which are generated through the aforementioned sputtering of the partition 44 and injected into the plasma atmosphere 34. Thus, atoms, clusters, or fine particles exhibiting catalytic performance may be deposited in the interiors and/or on the surfaces of the thus-formed carbon nanowalls. The carbon nanowalls containing such atoms, clusters, or fine particles are applicable to, for example, a material for an electrode of a fuel cell, since the carbon nanowalls can exhibit high catalytic performance.

Plasma discharge means 20 is configured so as to serve as a parallel plate-type capacitively coupled plasma (CCP) formation mechanism. The plasma discharge means 20 includes a first electrode 22 and a second electrode 24, each of which has a generally disk shape. These electrodes 22 and 24 are disposed in the reaction chamber 10 so as to be generally parallel to each other. Typically, the first electrode 22 is disposed above the second electrode 24. The first electrode (cathode) 22 is connected to a power supply (not illustrated) via a matching network (not illustrated). The power supply and the matching network can generate at least one of RF waves (e.g., 13.56 MHz), UHF waves (e.g., 500 MHz), VHF waves (e.g., 27 MHz, 40 MHz, 60 MHz, 100 MHz, and 150 MHz), and microwaves (e.g., 2.45 GHz). The power supply and the matching network are configured so that at least RF waves can be generated.

The second electrode 24 is disposed in the reaction chamber 10 so as to be away from the first electrode 22. The distance between the electrodes 22 and 24 may be, for example, about 0.5 to about 10 cm. In Embodiment 1, the distance is about 5 cm. The second electrode 24 is grounded. For production of carbon nanowalls, the substrate (base) 5 is placed on the second electrode 24. For example, the substrate 5 is placed on the top surface of the second electrode 24 so that a surface of the base 5 on which carbon nanowalls are produced is exposed (i.e., faced to the first electrode 22). The second electrode 24 includes therein a heater 25 (e.g., a carbon heater) serving as base temperature control means. Optionally, the temperature of the substrate 5 may be controlled by operating the heater 25.

The reaction chamber 10 is provided with a raw material inlet 12 through which a raw material (raw material gas) can be supplied from a supply source (not illustrated). In a preferred mode, the inlet 12 and an oxygen inlet 13 are provided so that a raw material gas and oxygen gas can be supplied between the first electrode (upper electrode) 22 and the second electrode (lower electrode) 24. A supply tube 15 extending from the oxygen inlet 13 in the reaction chamber 10 to the vicinity of the substrate 5 is provided so as to be parallel to the substrate 5. The supply tube 15 has a discharge outlet 17 provided in the vicinity of the substrate 5. The inlets 14 are provided so that radicals can be introduced between the first electrode 22 and the second electrode 24. The reaction chamber 10 also includes a discharge outlet 16. The discharge outlet 16 is connected to, for example, a vacuum pump (not illustrated) serving as pressure control means (pressure reducing means) for controlling the pressure in the reaction chamber 10. In a preferred mode, the discharge outlet 16 is provided below the second electrode 24.

Microwaves (e.g., 2.45 GHz) are introduced directly into the radical generation device 40, and hydrogen plasma is formed from supplied hydrogen gas in the plasma formation chamber 46, whereby H radicals are generated.

By means of the apparatus 3 having the aforementioned configuration, carbon nanowalls can be produced through, for example, the following procedure. Specifically, the base 5 is placed on the second electrode 24, and a gaseous raw material (raw material gas) 32 and oxygen gas 33 are supplied through the raw material inlet 12 and the oxygen inlet 13, respectively, into the reaction chamber 10 at specific feed rates. A gaseous radical source (radical source gas) 36 is supplied through a radical source inlet 42 into the plasma formation chamber 46 at a specific feed rate. The vacuum pump (not illustrated) connected to the discharge outlet 16 is operated so that the pressure in the reaction chamber 10 (i.e., the total pressure of the partial pressure of the raw material gas, the partial pressure of oxygen gas, and the partial pressure of the radical source gas) is about 10 to about 2,000 mTorr. The preferred ratio of the feed rate of the raw material gas to that of the radical source gas may vary with, for example, the types (compositions) of these gases, or the properties and characteristics of carbon nanowalls of interest. When, for example, a C1 to C3 fluorocarbon is employed as a raw material gas, and hydrogen gas is employed as a radical source gas, these gases may be supplied so that the ratio of the feed rate of the raw material gas to that of the radical source gas (e.g., the feed rate ratio when these gases are supplied at similar temperatures) is 2/98 to 60/40. The feed rate ratio is preferably 5/95 to 50/50, more preferably 10/90 to 30/70. The ratio of the feed rate of the oxygen gas to that of the raw material gas is preferably 1/100 to 2/10, more preferably 2/100 to 12/100.

Thus, a plasma of the raw material gas 32 and a plasma of the oxygen gas 33 are formed generally between the first electrode 22 and the second electrode 24, to thereby provide the plasma atmosphere 34. Microwaves (e.g., 2.45 GHz) are introduced into the waveguide 47 for decomposing the radical source gas 36 in the plasma formation chamber 46, to thereby generate the radicals 38. The thus-generated radicals 38 are introduced through the radical inlets 14 into the reaction chamber 10, and injected into the plasma atmosphere 34, whereby the raw material gas plasma forming the plasma atmosphere 34 is mixed with the radicals 38 supplied from outside the atmosphere. Thus, carbon nanowalls can be grown on the top surface of the substrate 5 placed on the second electrode 24. In this case, preferably, the temperature of the substrate 5 is maintained at about 100 to about 800° C. (more preferably, about 200 to about 600° C.) by means of, for example, the heater 25.

Next will be described examples in which a carbon nanostructure was produced by means of the aforementioned apparatus 3, and characteristics of the thus-produced carbon nanostructure were evaluated.

### EXAMPLE 1

In Example 1, C₂F₆ was employed as the raw material gas 32. Hydrogen gas (H₂) was employed as the radical source gas 36. A silicon (Si) substrate having a thickness of about 0.5 mm was employed as the substrate 5. The silicon substrate 5 contains substantially no catalyst (e.g., metal catalyst). The silicon substrate 5 was placed on the second electrode 24 so that the (100) plane of the substrate 5 faced the first electrode 22. The raw material gas 32 (i.e., C₂F₆) was supplied through the raw material inlet 12 into the reaction chamber 10; the oxygen gas 33 was supplied through the oxygen inlet 13; and the radical source gas 36 (i.e., hydrogen gas) was supplied through the radical source inlet 42. The reaction chamber 10 was evacuated through the discharge outlet 16.

C₂F₆ was supplied into the reaction chamber 10 at 50 sccm; hydrogen gas was supplied into the plasma formation chamber 46 at 100 sccm; and oxygen gas was supplied into the reaction chamber 10 at 0, 2, or 5 sccm. Evacuation conditions were controlled so that the total pressure was adjusted to about 1.2 Torr. While the raw material gas 32 and the oxygen gas 33 were supplied under the aforementioned conditions, an RF power (13.56 MHz, 100 W) was applied from the power supply to the first electrode 22, and RF waves were applied to the raw material gas 32 (C₂F₆) and the oxygen gas 33 contained in the reaction chamber 10. Thus, a plasma of the raw material gas 32 and a plasma of the oxygen gas 33 were formed, whereby the plasma atmosphere 34 was provided between the first electrode 22 and the second electrode 24.

While the radical source gas 36 was supplied under the aforementioned conditions, microwaves were introduced into the waveguide 47, and microwaves were applied to the radical source gas 36 (H₂) contained in the plasma formation chamber 46. The thus-generated H radicals were introduced through the radical inlets 14 into the reaction chamber 10. Thus, a carbon nanostructure was grown (formed) on the (100) plane of the silicon substrate 5. In Example 1, the nanostructure was grown for 20 minutes (in the case of supply of no oxygen gas) or 40 minutes (in the case of supply of oxygen gas). During this growth period, the temperature of the substrate 5 was maintained at about 500° C. by using, as necessary, the heater 25 or a cooling apparatus (not illustrated).

Carbon nanowalls produced in Example 1 were observed under a scanning electron microscope (SEM). FIGS. 2(a) to 2(c) are SEM images of cross sections of carbon nanowalls produced in Example 1, and FIGS. 2(d) to 2(f) are SEM images of the respective corresponding carbon nanowalls as viewed from above. FIGS. 2(a) and 2(d) are SEM images of carbon nanowalls corresponding to the case where no oxygen gas was supplied to the plasma atmosphere. FIGS. 2(b) and 2(e) are SEM images of carbon nanowalls corresponding to the case where oxygen gas was supplied at 2 sccm; i.e., the ratio of the feed rate of oxygen gas to the total feed rate (150 sccm) of C₂F₆ (50 sccm) and hydrogen gas (100 sccm) was 1.3%. FIGS. 2(c) and 2(f) are SEM images of carbon nanowalls corresponding to the case where oxygen gas was supplied at 5 sccm; i.e., the ratio of the feed rate of oxygen gas to the total feed rate (150 sccm) of C₂F₆ (50 sccm) and hydrogen gas (100 sccm) was 3.2%.

In the case where no oxygen gas was supplied, carbon nanowalls were grown at a rate of 60 nm/min., and the thus-grown carbon nanowalls had a height of 1,200 nm. However, as is clear from FIGS. 2(a) and 2(d), each carbon nanowall had numerous branches and did not extend smoothly.

In contrast, in the case where oxygen gas was supplied at 2 sccm, carbon nanowalls were grown at a rate of 19 nm/min., and the thus-grown carbon nanowalls had a height of 760 nm. As is clear from FIGS. 2(b) and 2(e), there were produced carbon nanowalls which had no branching and extended smoothly.

In the case where oxygen gas was supplied at 5 sccm, carbon nanowalls were grown at a rate of 22 nm/min., and the thus-grown carbon nanowalls had a height of 890 nm. As is clear from FIGS. 2(c) and 2(f), there were produced carbon nanowalls which had no branching and extended smoothly.

Subsequently, the thus-produced carbon nanowalls were subjected to Raman spectroscopy. The results are shown in FIG. 3. Spectrum a corresponds to the case where no oxygen gas was supplied; spectrum b corresponds to the case where oxygen gas was supplied at 2 sccm; and spectrum c corresponds to the case where oxygen gas was supplied at 5 sccm. As is clear from FIG. 3, the half-width of band D is smaller in spectrum b or c (corresponding to the case where carbon nanowalls were grown under supply of oxygen gas) than in spectra a. This suggests that carbon nanowalls grown under supply of oxygen gas exhibit improved crystallinity. As is also clear from FIG. 3, the intensity of band G is higher in spectrum b or c than in spectra a. This suggests that carbon nanowalls grown under supply of oxygen gas exhibit improved SP2-related crystallinity. As is also clear from FIG. 3, the intensity of band D′ is lower in spectrum b or c than in spectra a. This suggests that carbon nanowalls grown under supply of oxygen gas contain reduced amounts of microcrystalline components and have reduced edges.

In the experiments described above, C₂F₆ was employed as a raw material gas. However, the raw material gas employed may be a CF-based gas (e.g., fluorocarbon such as CF₄ or fluorohydrocarbon such as CHF₃), since carbon nanowalls of high quality are formed by addition of oxygen plasma (formed through introduction of oxygen gas) to a plasma atmosphere containing carbon and fluorine in the presence of hydrogen radicals. Since such a plasma atmosphere contains the same constituent elements as those in the case where hydrogen radicals are added to C₂F₆, oxygen plasma can be formed from oxygen gas supplied to the raw material gases forming the plasma atmosphere. As is clear from data shown in FIG. 3, when the ratio of the flow rate of oxygen gas to the total flow rate of C₂F₆ gas and hydrogen gas is at least 1.3%, grown carbon nanowalls exhibit improved crystallinity. When the flow rate ratio is 3.2%, grown carbon nanowalls exhibit further improved crystallinity. Thus, as shown in FIG. 3, when the ratio of the flow rate of oxygen gas to the total flow rate of hydrogen gas and a raw material gas other than C₂F₆ is at least 1.3 to 3.2%, grown carbon nanowalls exhibit improved crystallinity. This suggests that when the ratio of the feed rate of oxygen gas to that of a raw material gas is about 0.5% (i.e., when a small amount of oxygen is present in a plasma atmosphere), grown carbon nanowalls have good crystallinity. In contrast, when an excessively large amount of oxygen gas is supplied, the oxygen gas may inhibit crystal growth of carbon nanowalls from a raw material gas. Therefore, the maximum of the ratio of the flow rate of oxygen gas to that of a raw material gas is considered to be 5% to 10%. Conceivably, such a flow rate ratio may be applied to the case where a CF-based or CHF-based raw material gas other than C₂F₆ gas is employed, since the resultant plasma atmosphere contains the same constituent elements as those in the case where C₂F₆ is employed. The effects of the present invention are obtained by the action of oxygen atoms. Therefore, a small amount of O radicals or OH radicals may be effectively employed, or a mixture of these radicals may be employed.

A gas which generates oxygen atom radicals or radicals of an oxygen-atom-containing molecule is supplied in the vicinity of a base on which carbon nanowalls are formed, or supplied in parallel to the base. As has been shown, in this case, even when the flow rate of such a gas is high (e.g., about 10 sccm), a plasma thereof is stably formed, and the base is not etched. As has also been shown, when such a gas is supplied at a location away from the base, the resultant plasma is unstable, and the base is etched. Oxygen atom radicals or radicals of an oxygen-atom-containing molecule may be generated in a chamber different separate from a reaction chamber, and the radicals may be supplied in the vicinity of the base or in parallel to the growth surface of the base.

### INDUSTRIAL APPLICABILITY

Carbon nanowalls produced through the method of the present invention are useful in various applications, including semiconductor devices and fuel cells.

1. A method for producing carbon nanowalls, comprising forming carbon nanowalls on a surface of a base in a plasma atmosphere containing hydrogen and a raw material containing at least carbon and fluorine as its constituent elements,
characterized in that oxygen atom radicals or radicals of an oxygen-atom-containing molecule are added to the plasma atmosphere.

2. A method for producing carbon nanowalls according to claim 1, wherein the hydrogen plasma is generated through injecting, to the plasma generation site, hydrogen radicals generated in at a site different from the plasma atmosphere.

3. A method for producing carbon nanowalls according to claim 1, wherein the raw material is at least one member selected from among C₂F₆, CF₄, and CHF₃.

4. A method for producing carbon nanowalls according to claim 2, wherein the raw material is at least one member selected from among C₂F₆, CF₄, and CHF₃.
